(19) United States
(12) Patent Application Publication
(10) Pub. No.: US 2009/0267634 A1
(43) Pub. Date: Oct. 29, 2009

(54) Switch Module for Semiconductor Characteristic Measurement and Measurement Method of Semiconductor Characteristics

(75) Inventors: Hiroshi Nada, Tokyo (JP); Yoichi Kuboyama, Tokyo (JP); Atsushi Mikata, Tokyo (JP)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Santa Clara, CA (US)

(21) Appl. No.: 12/324,918

(22) Filed: Nov. 28, 2008

Related U.S. Application Data
(60) Provisional application No. 61/047,790, filed on Apr. 25, 2008.

(51) Int. Cl. G01R 31/26

(52) U.S. Cl. 324/769

(57) ABSTRACT

A switch module is disclosed for semiconductor characteristic measurement and a semiconductor characteristic measurement method is disclosed with which the impact of the recovery effect after stress signal elimination is reduced in BTI testing. The switch module for semiconductor characteristic measurement includes a first input terminal for receiving stress signals from a stress signal source, a second input terminal for receiving signals from a first non-stress signal source, a first output terminal for outputting output signals, and a switch part for controlling the connection of the first output terminal and the first input terminal or the second input terminal, wherein the switch part detects a first voltage transition of the signals transmitted to the second input terminal and modifies the connection.

This application claims the benefit of U.S. Provisional Application No. 61/047,790 filed 25 Apr. 2008, which is incorporated by reference herein in its entirety.

### BACKGROUND

This disclosure relates to technology for semiconductor characteristic measurement.

Complementary metal-oxide silicon semiconductors (CMOS semiconductors) are widely used for today's electronic devices. These CMOS semiconductors have p channel field effect transistors (PMOSFET) and n channel field effect transistors (NMOSFET). Attention is focused on the problem of a shift in the Vth due to PMOSFET internal negative bias temperature instability (NBTI) as a result of a reduction in the physical size of today's FET and a reduction in the FET threshold voltage (Vth). NBTI is considered a degradation that is generated when a negative bias is applied to the gate terminal of a PMOSFET. Moreover, the same problem of Vth shift is confirmed as a PBTI (positive bias temperature instability) in the NMOSFET. PBTI is described as a degradation due to the application of positive bias to the gate terminal of an NMOSFET. Moreover, there are a variety of BTI testing methods and measurement methods for measuring the BTI of NBTI and PBTI.

Attention is being focused on testing for NBTI wherein in addition to conventional DC (direct current) stress signals, pulse signals are applied as AC (alternating current) stress to the gate of a PMOSFET. A test circuit system that uses such AC stress signals is cited by M. Li et al. in Understand NBTI Mechanism by Developing Novel Measurement Techniques (IEEE Transactions on Device and Materials Reliability, Vol. 8, No. 1, March, 2008, pp 62-71). As cited in the Li text and by A. Krishnan et al., in Material Dependence of Hydrogen Diffusion: Implications for NBTI Degradation (IEDM Technical Digest, 2005, IEEE) it is important to shorten the time-lag until the gate voltage of a predetermined measurement condition is applied and the DC measurement of the drain current is accomplished after the AC stress is removed in the measurement. This is because the drain current shifts due to the generation of a recovery effect arising from this time-lag and it is therefore impossible to measure the exact amount of FET degradation.

According to the Li text, a pulse generator is used to apply the pulse and an oscilloscope is used to measure the drain current. However, in order to measure drain current with precision, it is preferred that an SMU (source measure unit or source monitor unit) housed inside the DC measurement instrument or the semiconductor analyzer is used instead of an oscilloscope. However, the GP-IB (general purpose interface bus) used to control these measurement instruments is not intended for real time control and it is difficult to synchronize the low-speed SMU measurement with the high-speed pulse signals. Therefore, there is a problem in that when BTI is measured using a pulse generator and an SMU, it is impossible to disregard the time interval from when the application of pulse signals stops until when the drain current is measured.

Today, On-The-Fly VTH Measurement for Bias Temperature Instability Characterization (Keithley, Application Note No. 2814, 2007) and ACS Integrated Test System for NBTI Testing (Keithley, Application Note No. 2848, 2007) cite a method wherein DC stress is applied to a gate using an SMU; a method wherein drain current is measured using −50 mV as the drain current voltage when measurement is performed after eliminating DC stress; a method whereby drain current is measured just before eliminating DC stress with drain voltage constant at −50 mV whether DC stress is applied or eliminated, and a method whereby DC drain current is always repeatedly measured whether DC stress is applied or eliminated. Moreover, Accurate NBTI Characterization Using Timing-on-the-Fly Sampling Mode (Agilent Technologies, Application Note B1500-6, Nov. 1, 2006) cites a method whereby the drain voltage is transitioned to measurement voltage in synchronization with the voltage transition of gate voltage from DC stress voltage to measurement voltage.

On the other hand, Introducing Pulsing into Reliability Tests for Advanced CMOS Technologies (P. Hulbert et al., Keithley, White Paper No. 2638, 2005) cites a method wherein AC stress and swept voltage waveform are applied as the gate voltage.

A multiplexer that is controlled by a control device such that it switches between a stress power source and a measurement apparatus in semiconductor reliability testing is cited in USP 2006/0208754A1.

### SUMMARY

An object of the present disclosure is to provide a switch module for semiconductor characteristic measurement with which the impact of the recovery effect after stress signal elimination is reduced in BTI testing, and a method therefor.

Another object of the present disclosure is to provide a switch module for semiconductor characteristic measurement with which the Vg-Id characteristic of the Vth measurement of a device under test is performed at high speed in BTI testing, and a method therefor.

The present disclosure provides a switch module for semiconductor characteristic measurement, includes a first input terminal for receiving stress signals from a stress signal source, a second input terminal for receiving signals from a first non-stress signal source, a first output terminal for outputting output signals, and a switch part for controlling the connection of the first output terminal and the first input terminal or the second input terminal, wherein the switch part detects a first voltage transition of the signals transmitted to the second input terminal and modifies the connection.

Moreover, the present disclosure provides a semiconductor characteristic measurement method which has steps of connecting a stress signal source to the first terminal of a DUT via a switch module, connecting a first non-stress signal source to the switch module, applying stress signals from the stress signal source to the first terminal, outputting a first voltage from the first non-stress signal source, outputting a second voltage from the first non-stress signal source, connecting the first non-stress signal source to the first terminal which is triggered by the switch module according to the transition from the first voltage to the second voltage, and measuring the current flowing to the second terminal of the DUT is measured.

### BRIEF DESCRIPTION OF THE DRAWINGS

The foregoing aspects and other features of the presently disclosed embodiments are explained in the following description, taken in connection with the accompanying drawings, wherein:

FIG. 1 is a block diagram of a semiconductor characteristic measurement apparatus that is an example of the presently disclosed embodiments.

FIG. 2 is a timing chart describing the operation of the apparatus in FIG. 1.

FIG. 3 is another timing chart describing the operation of the apparatus in FIG. 1.

FIG. 4 is a block diagram of a semiconductor characteristic measurement apparatus that is another example of the presently disclosed embodiments.

FIG. 5 is a timing chart describing the operation of the apparatus in FIG. 4.

FIG. 6 is a block diagram of a semiconductor characteristic measurement apparatus that is yet another working example of the presently disclosed embodiments.

FIG. 7 is a block diagram of a semiconductor characteristic measurement apparatus that is yet another working example of the presently disclosed embodiments.

FIG. 8 is a block diagram of a semiconductor characteristic measurement apparatus that is still another working example of the presently disclosed embodiments.

FIG. 9 is a timing chart describing the operation of the apparatus in FIG. 8.

FIG. 10 is a block diagram of a semiconductor characteristic measurement apparatus that is still another working example of the presently disclosed embodiments.

FIG. 11 is a timing chart describing the operation of the apparatus in FIG. 10.

FIG. 12 is a block diagram of a semiconductor characteristic measurement apparatus that is still another working example of the presently disclosed embodiments.

### DETAILED DESCRIPTION

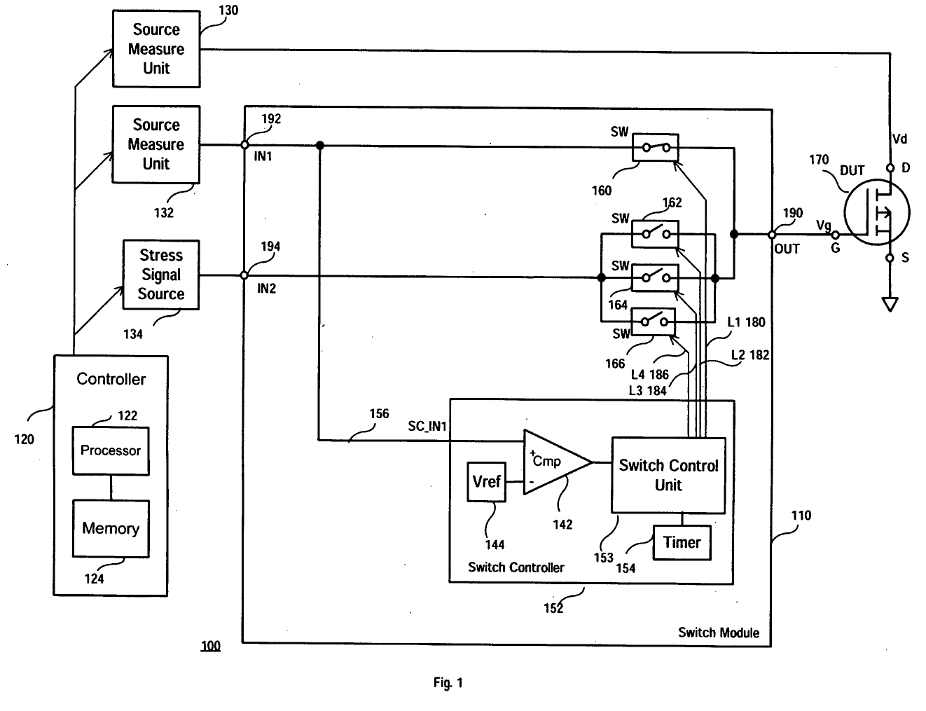

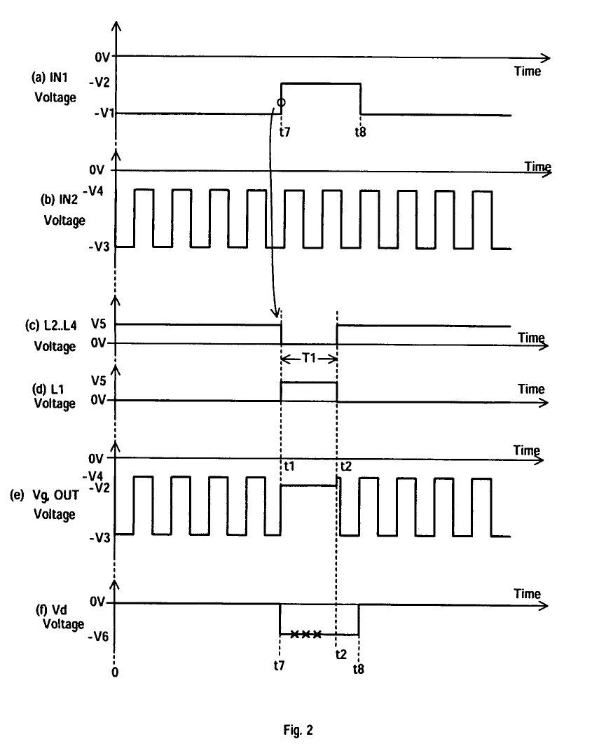

Working examples of the present disclosure will be described while referring to FIGS. 1 and 2.

It should be noted that in the present disclosure, the SMU (source measure unit or source monitor unit) is a measurement apparatus that has a voltage application (voltage force) or a current application (current force) function and is capable of simultaneously measuring a voltage or current, when voltage is being applied. It has the function of simultaneously measuring voltage when current is being applied. Even though it is called an SMU, in the present disclosure this unit does not necessarily have all of the above-mentioned functions, and it can be substituted for a structure wherein it has only the functions that will be used and is a voltage source or current source that performs equivalent operations or a combination of these with a voltammeter or ammeter.

FIG. 1 shows a semiconductor characteristic measurement apparatus 100, which is one example of the present disclosure. A DUT (device under test) 170 is described here as a PMOSFET. DUT 170 has a gate terminal G, a drain terminal D, and a source terminal S, and the voltage at gate terminal G is Vg and the voltage at drain terminal D is Vd. An SMU 130 is connected to drain terminal D and performs voltage application (voltage force). Moreover, SMU 130 measures the current while applying voltage in accordance with a command from a controller 120.

A stress signal source (SSS) 134 and an SMU 132 are connected to gate terminal G via a switch module 110. SSS 134 is a DC or an AC stress signal generator and is the signal source that feeds stress signals to the DUT. SSS 134 can use a pulse generator or a signal generator when feeding AC stress signals. An SMU, a DC power source, a battery, or the like can be used when feeding DC stress signals. It should be noted that SMU 132 is a signal source that feeds DC signals that satisfy the DUT measurement conditions (such as standard voltage) rather than stress signals. SMU 130 and 132 can be regarded as non-stress signal sources, as is clear from the effect on the DUT.

Switch module 110 switches between SMU 132 connected to an IN1 terminal 192 and SSS 134 connected to an IN2 terminal 194 and feeds signals from an OUT terminal 190 to the DUT. Thus, switch module 110 performs switching that is triggered by a voltage transition of the signals transmitted to IN1 terminal 192. That is, it should be noted that the signals transmitted to IN1 terminal 192 also have a trigger function and the module therefore does not have a dedicated switching trigger signal terminal.

IN1 terminal 192 is connected to OUT terminal 190 via a relay SW160 and IN2 terminal 194 is connected to OUT terminal 190 via multiple relays SW 162, 164, and 166 connected in parallel. The signals of IN1 terminal 192 are connected to a switch controller 152 by a line 156. Switch controller 152 monitors the signals of IN1 terminal 192 using a SC_IN1 terminal to which line 156 is connected and controls the opening and closing of relays 160 through 166 by control lines L1 180, L2 182, L3 184, and L4 186.

Switch controller 152 includes a comparator 142 that connects the input of SC_IN1 terminal to the noninverted input terminal, performs a comparison with the reference voltage of a reference voltage source Vref 144 connected to the inverted input terminal, and outputs detection signals that will switch the output to effective/on or ineffective/off when there has been a transition that exceeds the reference voltage. The detection signal output of comparator 142 is input to a switch control unit 153 and control lines 180 through 186 are controlled such that relay 160 is closed for a predetermined time by a timer 154 and relays 162 through 166 are simultaneously opened for a predetermined time. It should be noted that switch control unit 153 can also include a delay line for delaying the signals from comparator 142 arbitrarily and a buffer for buffered amplification of signals of SC_IN1 terminal 156.

SMUs 130 and 132 and SSS 134 are connected to and controlled by a controller 120.

Controller 120 includes a processor 122 and a memory 124, and sends control signals to SMUs 130 and 132 and SSS 134 and controls measurement. The programs that control measurement and the data of the measurement results read from each SMU are housed in memory 124. Controller 120 is, for instance, a computer such as a PC (personal computer) loaded with Microsoft Windows™ OS. Processor 122 can be, for instance, an Intel Core™, or other CPU, MPU or other general-purpose processor, or a special processor, such as a DSP, ASIC, gate array, or the like, and memory 124 can be a variety of memories, such as a RAM or other volatile memory, a ROM, a flash memory, or another non-volatile memory, a HDD (hard disk drive), a CD drive, or a DVD drive. A control bus such as a GP-IB is used to connect controller 120 and SSS 134 and SMUs 130 and 132.

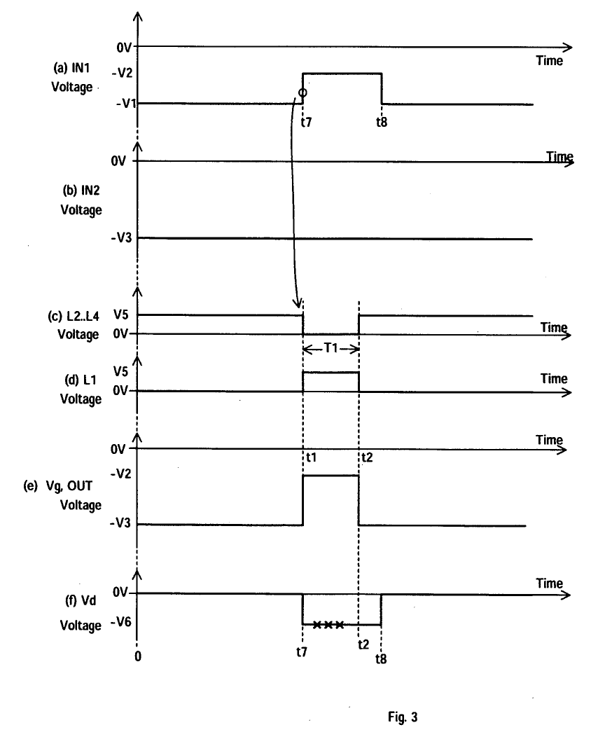

Next, the operation of switch module 110, SMU 130 and 132, and SSS 134 in FIG. 1 will be described while referring to FIGS. 2 and 3. FIG. 2 shows the timing chart when SSS 134 is an AC stress signal source and FIG. 3 shows the timing chart when SSS 134 is a DC stress signal source.

In FIG. 2, voltage −V1 signals are initially output from source measure unit 132 and transmitted to IN1 terminal 192, as shown in FIG. 2(a). Pulse signals of voltage −V3 through −V4 are output from SSS 134 and transmitted to IN2 terminal 194, as shown in FIG. 2(b).

At the initial timing (time 0) when pulse signals in FIG. 2(b) are applied, relay SW 160 of switch module 110 is open and SW162 through 166 are closed. Consequently, the initial status is that pulse signals of SSS 134 transmitted to IN2 terminal 194 are transmitted to OUT terminal 190 and are transmitted to gate terminal G of the DUT.

In FIG. 2, when AC stress signals are applied to IN2 terminal 194 and the voltage of IN1 terminal 192 transitions from −V1 to −V2 at time t7, switch controller 152 detects this transition, opens relay SW 162 through 166 (transition from V5 to 0V at time t1 in FIG. 2(c)), and at the same time closes relay SW 160 (transition from 0V to V5 at time t1 in FIG. 2(d)). As a result, the output of the OUT terminal changes from the voltage −V3 of a pulse signal from SSS 134 to the DC signal of voltage −V2 of SMU 132 at time t1 (transition from −V3 to −V2 in FIG. 2(e)). Next, SMU 130 transitions drain voltage from 0V to −V6 at time t7 and measures drain current (X marks from time t7 to t2 in FIG. 2(f). SMU 132 at this time can also simultaneously measure gate voltage. The relationship between time t7 and t1 is t7<t1.

It should be noted that although clock (square wave) signals were described as the AC stress signals, these signals are not limited to clock signals and a variety of waveforms, such as pulse signals having various duty ratios and a ramp waveform can be applied.

Next, switch controller 152 uses timer 154 stored inside the controller to open relay 160 and to close relays 162 through 166 at time t2, which is a predetermined time T1 after time t1. The transition at this time t2 is shown in FIGS. 2(c) through (e). These figures show that stress signals are re-applied to OUT terminal 190 at time t2. As a result, it is possible to switch from the application of voltage −V2 for DC measurement to the application of pulse voltage and quickly restore gate voltage Vg to stress application status regardless of the voltage of terminal IN1.

In FIG. 3, initially signals of voltage −V1 are output from SMU 132 and transmitted to IN1 terminal 192, as shown in FIG. 3(a). DC stress signals of voltage −V3 are output from SSS 134 and transmitted to IN2 terminal 194, as shown in FIG. 3(b). The initial status of relays 160 through 166 is the same as in FIG. 2.

In FIG. 3, when DC stress signals are applied to IN2 terminal 194 and the voltage of IN1 terminal 192 transitions from −V1 to −V2 at time t7, switch controller 152 detects this transition, opens relays SW 162 through 166 (transition from V5 to 0V at time t1 in FIG. 3(c)), and at the same time closes relay SW 160 (transition from 0V to V5 at time t1 in FIG. 3(d)). As a result, the output of OUT terminal 190 changes from the voltage −V3 of a DC stress from SSS 134 to the DC signal of voltage −V2 of SMU 132 at time t1 (transition from −V3 to −V2 in FIG. 3(e)). Next, SMU 130 transitions drain voltage from 0V to −V6 at time t7 and measures the drain current (X marks from time t7 to t2 in FIG. 3(f)). SMU 132 at this time can also simultaneously measure the gate voltage. As in FIG. 2, the relationship between time t7 and t1 is t7<t1.

Next, switch controller 152 uses timer 154 stored inside the controller to open relay 160 and to close relays 162 through 166 at time t2, which is a predetermined time T1 after time t1. The transition at this time t2 is shown in FIGS. 3(c) through (e). These figures show that with regard to the voltage of the OUT terminal, stress signals are re-applied at time t2. As a result, with respect to gate voltage Vg, it is possible to switch from the application of voltage −V2 for DC measurement to the application of DC stress signals, regardless of the voltage of terminal IN1 192. Thus, it is possible to quickly restore gate voltage to the DC stress application status.

In FIGS. 2 and 3, the initial output voltage −V1 of SMU 132 is the voltage that is not applied to gate terminal G and any voltage can be selected taking into consideration the reference voltage of reference voltage source Vref 144 of comparator 142.

As previously described, measurement can be understood to be a repetition of the process of stress application application of DC measurement voltage to gate voltage and measurement of drain current stress re-application re-application of DC measurement voltage to gate voltage and measurement of drain current.

That is, the signals transmitted to the gate terminal are switched from stress signals to measurement signals with the transition of the output signals of SMU 132 as the trigger and the drain current is measured; therefore, it is possible to reduce the time delay from when the application of stress signals stops until the DC measurement, and it is possible to considerably reduce the impact of the recovery effect during BTI measurement. Furthermore, when the system is restored from DC measurement to stress application status, it is restored by the effect of timer 154 and not control from SMU 132; therefore, there is little overhead related to this recovery and it is possible to continue testing with reducing the generation of the recovery effect on the DUT by application of DC measurement voltage. In other words, by means of the measurement apparatus and measurement method disclosed in FIGS. 1 through 3, it is possible to provide high-speed BTI measurement with little impact from the recovery effect, regardless of whether the measurement apparatus is a measurement apparatus in which the response to the GP-IB is slow or a measurement apparatus having a fast response. In addition, by switching from an AC stress signal source to a DC stress signal source as SSS 134, or vice-versa, it is possible to easily compare AC stress and DC stress using the same measurement system.

It should be noted that the open and close control signal voltage of relays 160 through 166 (0V and V5); the input of comparator 142; the voltage values of the stress signals, −V3 and −V4; and the voltages from SMU 130 and 132, −V1, −V2, 0V, and −V6, are examples for the purpose of description and they can be increased or decreased in accordance with the DUT specifications and type and in order to adjust the actual measurement circuit.

A pulse generator such as Model 81110A made by Agilent Technologies, Inc. is used for SSS 134 when AC stress is applied, and 10 MHz signals are output as the pulse signals, for instance. An example of the SMU is an SMU module housed inside a B1500A Semiconductor Device Analyzer of Agilent, but these devices are not limited to these examples.

Preferably an SPST (single-pole single-throw) semiconductor relay, that is, an analog switch, is used for relays SW 160 through 166. In general, it is possible to open and close semiconductor relays for short periods of time, the turn-on resistance, however, is as high as 100 ohms. Therefore, there is a problem that it may happen to compose a low-pass filter with the stray capacitance in the output line of the relay. Consequently, it is difficult to build a wide-band transmission path when using a semiconductor relay. However, in the present disclosure, multiple relays connected to IN2 terminal 194, which is used for transmission of AC stress signals, are connected in parallel; therefore, the turn-on resistance can be reduced when compared to the case where the path is constructed from only one semiconductor relay. As a result, it is possible to guarantee a band that is wide enough to allow passage of AC stress signals, even taking into consideration the stray capacitance in the output lines of the relays.

When signals from SSS 134 are transmitted with relays 162, 164, and 166 simultaneously opened or closed, there is a chance that there will be an increase in the capacitive charge injection effect on the analog signal path from the digital control line having a small charge when the semiconductor switch, that is, the analog switch is turned on and off. Therefore, although not described in detail in FIGS. 2 and 3, switch control unit 153 controls the process such that opening and closing of relays 162, 164, and 166 is performed in succession with the timing shifted slightly, and the charge injection effect is reduced.

Furthermore, it is possible to limit the band and to bring the transmission path band to a band optimal for the pulse signals used by restricting the number of relays 162 through 166 that are turned on/closed in parallel. That is, when it becomes necessary to reduce the band of the transmission path, control is implemented such that the number of relays that close simultaneously is reduced.

In addition, the opening and closing of relays 160, 162, 164, and 166 is individually controlled by switch control unit 153; therefore, switch control unit 153 can have a structure such that the opening and closing of SSS 134 and SMU 132 are controlled by a break-before-make or make-before-break pattern in accordance with the application. It is possible to bring the alternating short time or the alternating break time to a desired time.

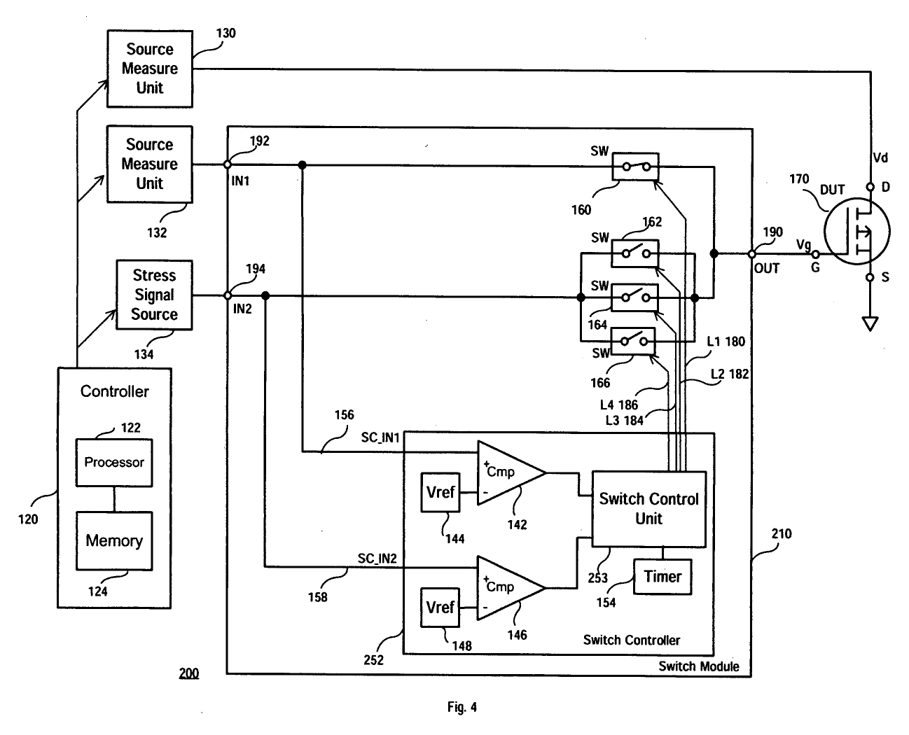

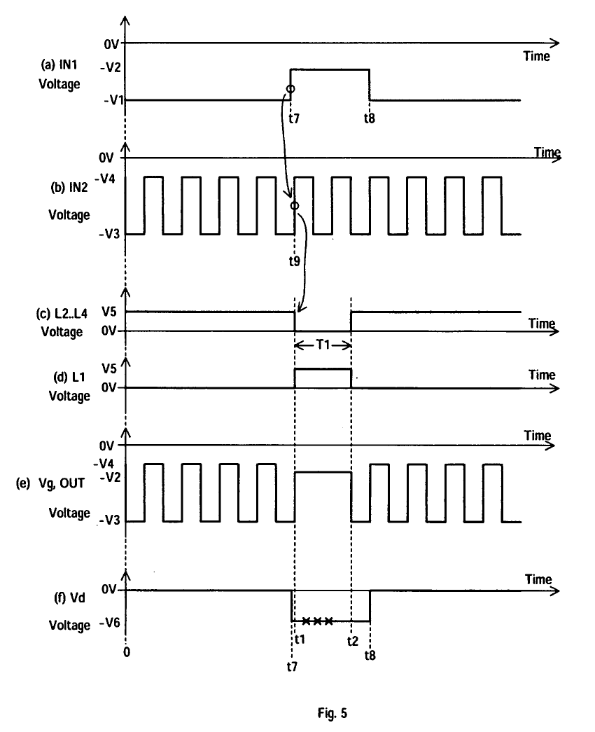

A semiconductor characteristic measurement apparatus 200, which is another working example of the present disclosure, will be described using FIGS. 4 and 5. It should be noted that the same reference numbers are used for the same structural parts as in FIG. 1.

By means of the working example in FIG. 4, switch module 110 of the working example in FIG. 1 is replaced by a different switch module 210. That is, in addition to IN1 terminal 192 being connected to the SC_IN1 terminal of switch controller 252 by line 156, switch module 210 has IN2 terminal 194 connected to the SC_IN2 terminal of switch controller 252 by line 158.

In addition to the structure of switch controller 152, switch controller 252 includes a comparator 146 that connects the input of the SC_IN2 terminal to the noninverted input terminal via line 158, performs a comparison with the reference voltage of an additional reference voltage source Vref 148 connected to the inverted input terminal, and outputs detection signals that will switch the output to effective/on or ineffective/off when a transition occurs that exceeds the reference voltage. The detection signal output of comparator 146 is input to a switch control unit 253. As a result, switch control unit 253 controls relays SW 160 through 166 via control lines 180 through 186 such that the signals connected to OUT terminal 190 are switched from stress signals to DC measurement signals, which is triggered by the detection of a voltage transition of signals from SMU 132 and further, the detection of a voltage transition of stress signals from SSS 134 within a predetermined time.

When referring to the timing chart in FIG. 5, in FIG. 5(a) comparator 142 detects the transition of the voltage of the IN1 terminal from −V1 to −V2 at time t7 and at time t9 in FIG. 5(b); comparator 146 detects the transition of the voltage of the IN2 terminal from −V3 to −V4. Relays 162 through 166 are opened and relay 160 is closed for time T1 beginning at time t1 and signals connected to OUT terminal 190 are switched from stress signals to DC measurement signals. The rest of the operation is as described in FIGS. 1 and 2. The relationship between times t7, t9 and t1 is t7<t9<t1.

It is possible to bring the stress status before and after the time zone of t1 through t2, when DC measurement is performed, to the same conditions by constructing switch module 252 in this way.

It should be noted that it is also possible to construct switch control unit 253 such that a predetermined delay is added to the detection signals from comparator 146 and the relays can be opened and closed when the stress signals are at a predetermined phase.

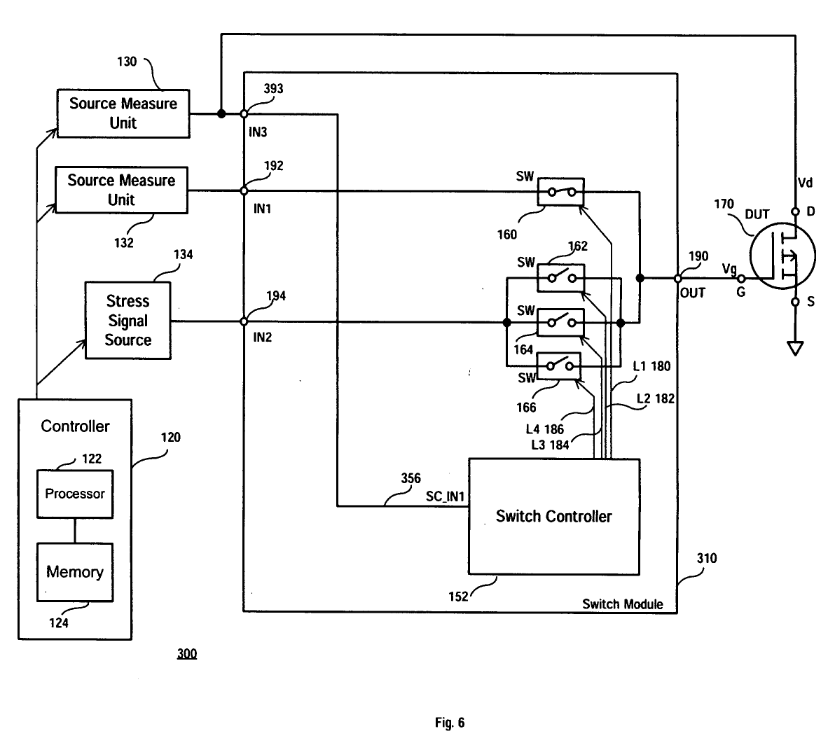

A semiconductor characteristic measurement apparatus 300, which is yet another working example of the present disclosure, will be described using FIG. 6. The same reference numbers are used in FIG. 6 for the structural elements that are the same as in FIG. 1.

By means of the working example in FIG. 6, it is shown that switching module 110 of the working example in FIG. 1, which switches from SSS 134 to SMU 132 when it is triggered by a voltage transition of SMU 132, is replaced with switching module 310, which switches when it is triggered by a voltage transition of another SMU, SMU 130.

In detail, the output of SMU 130 is connected to drain terminal D of DUT 170 and to an input terminal IN3 393 of switch module 310. At switch module 310, IN3 terminal 393 is connected to the SC_IN1 terminal of switch controller 152 via a line 356. The rest of the structure and operation is not described because it is the same as in FIG. 1. However, by means of this structure, it is possible to control relays 160 through 166 and switch between SSS 134 and SMU 132 with a transition of the Vd voltage, that is, the output of SMU 130 from 0V to −V6 in FIG. 2(f) as the trigger, and to output the same voltage waveform as in FIG. 2(e) to OUT terminal 190.

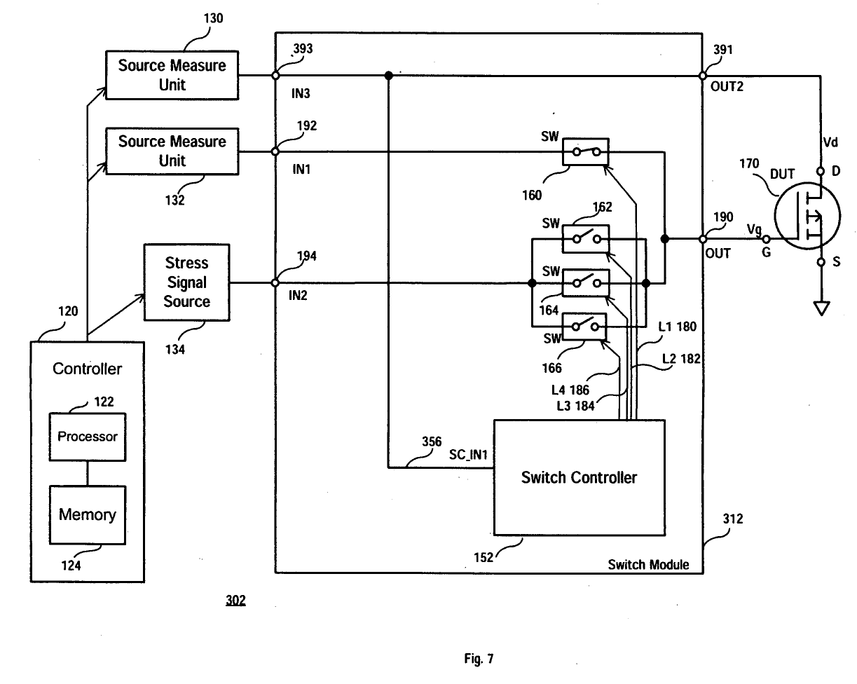

A semiconductor characteristic measurement apparatus 302, which is yet another working example of the present disclosure, will be described using FIG. 7. The same reference numbers are used in FIG. 7 for the structural elements that are the same as in FIG. 6.

The working example in FIG. 7 switches from SSS 134 to SMU 132 with the voltage transition of SMU 130 as the trigger, as in the working example in FIG. 6, but the switch module is changed from switch module 310 to a switch module 312.

In addition to the structure of switch model 310, switch module 312 has an output terminal OUT2 391 connected to input terminal IN3 393. By means of this structure, the wiring of SMU 130 is easily connected without direct wiring from SMU 130 to drain terminal D of DUT 170. The rest of the structure and operation are not described because they are the same as in FIG. 6.

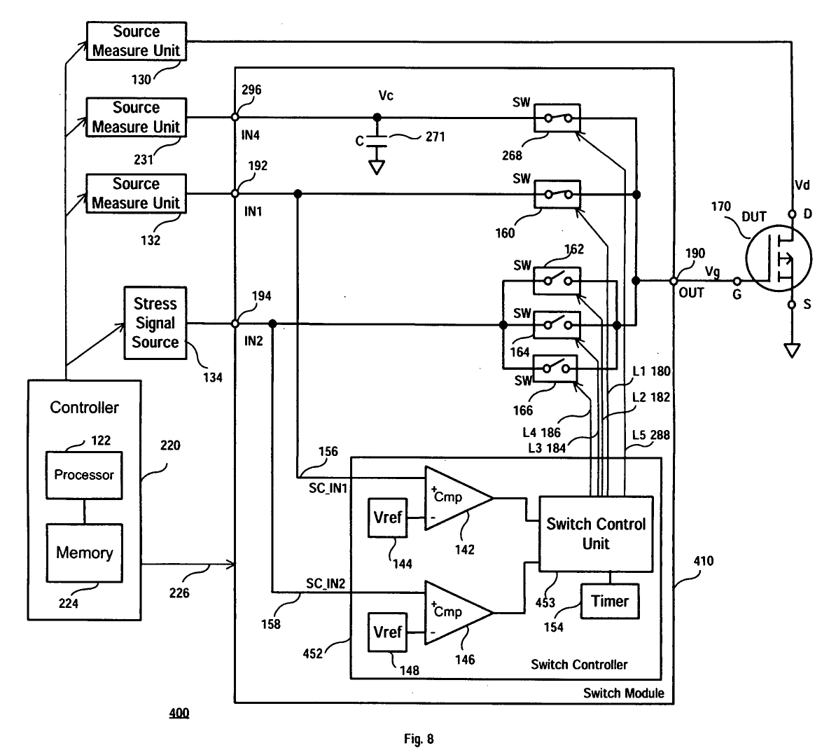

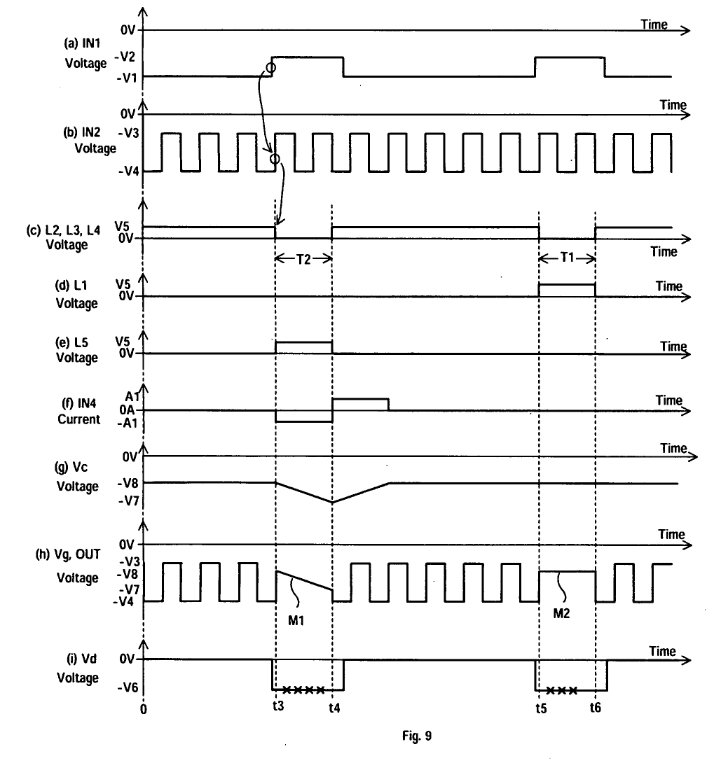

A semiconductor characteristic measurement apparatus 400, which is yet another working example of the present disclosure, will be described using FIGS. 8 and 9. The same reference numbers are used in FIG. 8 for the structural elements that are the same as in FIG. 4.

By means of the working example in FIG. 8, an SMU 231 is added to the working example in FIG. 4, and a switch module 410 houses a switch controller 452 and includes an input terminal IN4 296, a capacitor C 271 for voltage sweeping, a relay SW 268 for controlling opening/closing of the connection between terminal IN4 296 and OUT terminal 190, and a control line L5 288 for controlling relay 268. Switch controller 452 includes input terminals SC_IN1 and SC_IN2 connected to lines 156 and 158, as does switch controller 252 of the working example in FIG. 4, and reference voltage sources Vref 144 and 148 belonging to comparators 142 and 146, respectively. Switch controller 452 further includes a timer 154 and a switch control unit 453. Moreover, switch control unit 453 includes control lines 180 through 186 that control relays 160 through 166 and control line L5 288 that controls relay 268 and is connected to the output of comparators 142 and 146 and timer 154.

One terminal of capacitor C 271 for voltage sweeping is connected to input terminal IN4 296 and the other end is connected to a predetermined potential. This predetermined potential should be a constant potential, and can be ground potential. As a result, semiconductor characteristic measurement device 400 has a function for the high-speed measurement of a DUT Vg-Id characteristic (gate voltage-drain current characteristic).

In the past, macroscopic sweeping was performed by finely increasing or decreasing the output voltage from the SMU and application to the gate voltage Vg in order to measure the Vg-Id characteristic. Nevertheless, because this sweeping takes time, there is a chance that the Vg-Id characteristic after AC stress elimination will be impacted by a recovery effect. Therefore, by means of the present working example, a constant current flows from SMU 231 instead of outputting voltage from SMU 132 and an integrated waveform (ramp waveform) voltage that appears as voltage Vc of the terminal of capacitor C271 for voltage sweeping is transmitted to output terminal OUT 190 via relay SW 268. As a result, the Vg-Id characteristic is measured in a short period of time.

In addition to the function of controller 120 in FIG. 4, a controller 220 has a control line 226 and is capable of controlling the operation of switch module 410. A memory 224 inside controller 220 has the same structure as memory 124 in FIG. 4, but programs for controlling switch module 410 are housed inside. The other functions are not described because they are the same as in the working example in FIG. 4.

Next, the operation of semiconductor characteristic measurement apparatus 400 in FIG. 8 will be described using FIG. 9. First, when a voltage sweep waveform, that is, a ramp waveform, for Vg-Id characteristic measurement is output to DUT 170, a predetermined operating mode is set in switch module 410 via control line 226 from controller 220 and control is modified such that relay 160 remains open while relay 268 is opened/closed and the timer time of timer 154 is set to T2. Next, the signal output of SSS 134 and SMUs 130 and 132 is performed similarly between time 0 and t1 in FIG. 5 and relays SW 162 through 166 are opened as in FIG. 9(c) while relay SW 268 is closed (corresponding to time t3 in FIG. 9(d)). SMU 231 outputs voltage −V8 at time 0 and relay 268 is closed at time t3. Then current −A1 is output for predetermined time T2 (FIG. 9(f)). As a result, the terminal voltage V_{C} of capacitor C271 for voltage sweeping draws the ramp waveform of start voltage −V8 and stop voltage −V7 from time t3 to t4 as shown in FIG. 9(g).

After predetermined time T2 has passed, relay 268 is opened at time t4 and relays 162 through 166 are closed at time t4 by timer 154. As a result, the output voltage of output terminal OUT 190, that is, the gate voltage Vg of the DUT, becomes the ramp waveform of start voltage −V8 and stop voltage −V7, which is shown by waveform segment M1, for only time T2 from time t3 to t4 after the stress signals, as shown in FIG. 9(h), and stress signals are again transmitted thereafter. Drain current is repeatedly measured by SMU 130 for ramp waveform M1 from time t3 to t4 (X marks between time t3 and t4 in FIG. 9(i)), gate voltage is repeatedly measured by SMU 231, and the Vg-Id characteristic and/or Vth of DUT 170 are measured.

Then, beginning at time t4, SMU 231 outputs current −A1 and the charge that has charged capacitor C 271 is discharged.

Next, when the same BTI measurement as in FIG. 5 is performed after the above-mentioned Vg-Id characteristic measurement, the operating mode is modified and set in switch module 410 via control line 226 from controller 220, the control is modified such that relay 268 is always open and the timer time of timer 154 is brought to T1. The same signals as from time 0 to t1 in FIG. 5 are output from SSS 134 and SMUs 130 and 132, relay 160 is closed, and relays 162 through 166 are opened (time t5 of FIG. 9(c) through (i)). This time it is not necessary to output current from SMU 231 because Vg-Id characteristics are not being measured, and relay 268 remains open. Relays 162 through 166 are opened and relay 160 is closed only for predetermined time T1 from time t5 to t6 based on control by timer 154. Voltage −V2 is applied as the gate voltage in the form of a waveform segment M2 from time t5 to t6 in FIG. 9(h), and the drain current during this time is measured by SMU 130 (X marks between times t5 through t6 in FIG. 9(i)).

As described above, by means of semiconductor characteristic measurement apparatus 400 in FIG. 8, a high-speed measurement of Vg-Id characteristics after AC stress application is possible, and a DC measurement after AC stress application is also possible, as in the working example 4.

It should be noted that the above-mentioned working examples have been described with the intention of measuring Vg-Id characteristics, but it is also possible to use the above-mentioned working examples to measure the threshold voltage Vth. When the Vth is found by drawing a tangent line to the Vg-Id curve, it is possible to find the Vg-Id characteristic as described above and find the Vth from these results. Moreover, when the Vth is defined as the gate voltage Vg at which the drain current Id becomes a predetermined current, it is possible to repeatedly measure the drain current and the gate voltage by SMUs 130 and 231, respectively, beginning at time t3 and to find Vth from the measured gate voltage when the predetermined Id or approximately the predetermined Id is obtained, or from the interpolated value thereof.

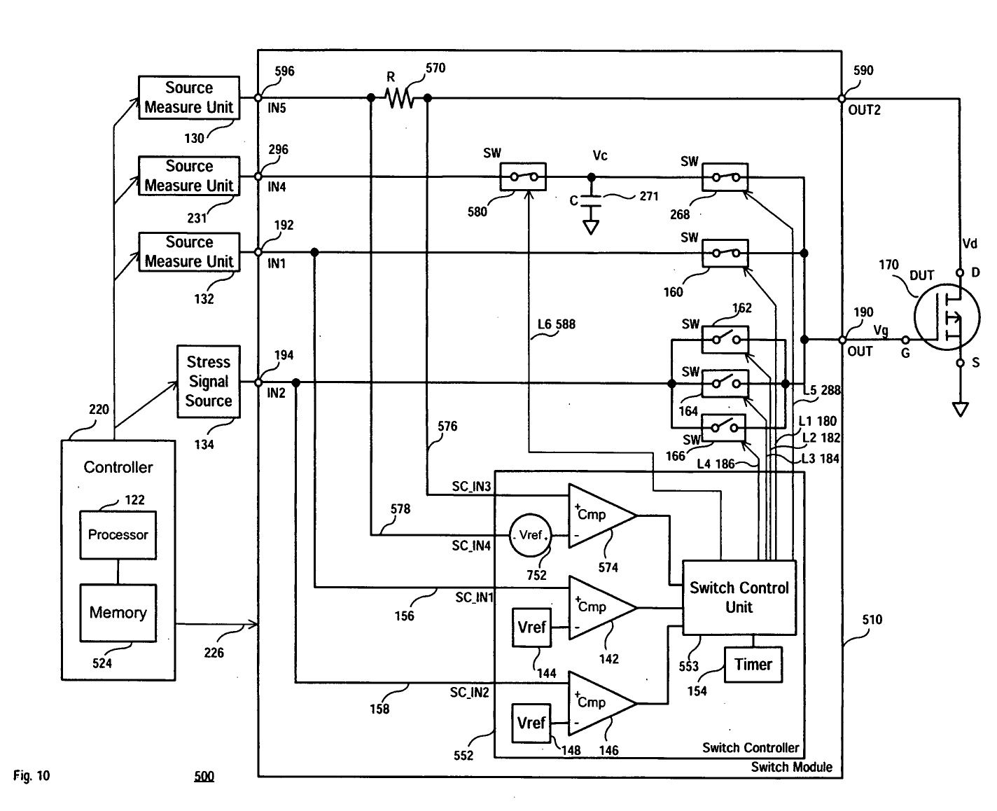

A semiconductor characteristic measurement apparatus 500, which is yet another working example of the present disclosure, will be described using FIG. 10. The same reference numbers are used in FIG. 10 for the structural elements that are the same as in FIG. 8.

The working example in FIG. 10 shows an example of a high-speed determination of the Vth based on the working example in FIG. 8. Here the Vth of DUT 170 is defined as the gate voltage when the drain current Id becomes a predetermined current.

A switch module 510 in the working example in FIG. 10 includes, in addition to switch module 410 in FIG. 8, an input terminal IN5 596 to which SMU 130 connected to the drain terminal is connected, and an output terminal OUT2 590 via a current detection resistor R570 for measuring the drain current that flows through terminal IN5 596. Furthermore, lines 576 and 578 for monitoring the voltage at both ends of current detection resistor R570 are connected to terminals SC_IN3 and SC-IN4 of a switch controller 552. There is also a relay SW 580 for opening and closing the connection between sweep capacitor C271 and input terminal IN4 296, and opening and closing of relay 580 is controlled by a control line L6 588 from a switch control unit 553.

As in the working example in FIG. 8, comparators 142 and 146 and timer 154 are connected to switch controller 552. In addition, the controller includes a comparator 574 for comparing the difference in voltage between both ends of current detection resistor R 570 and outputting detection signals when this difference is above a predetermined voltage difference, and switch control unit 553 to which this output is connected. Terminal SC_IN3 is connected to the noninverted input terminal of comparator 574 and terminal SC_IN4 is connected to the inverted input terminal via an offset voltage source Vref 752. Offset voltage source Vref 752 is set or configured such that when the current that flows through resistor R is equal to the value of the drain current that specifies Vth, comparator 574 outputs detection signals.

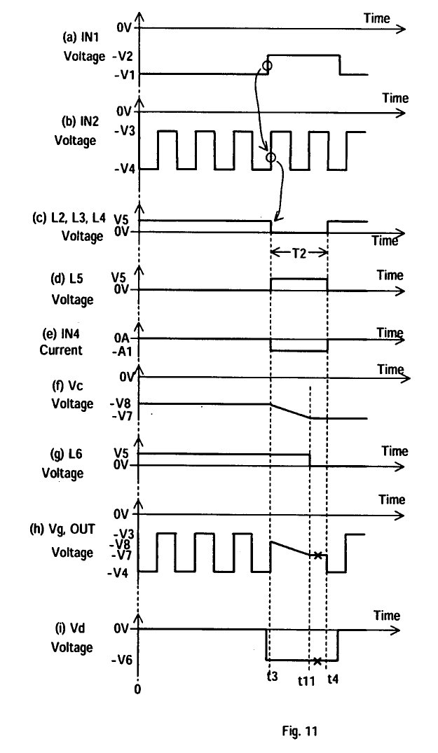

The operation of semiconductor characteristic measurement apparatus 500 will be described while referring to FIG. 11. The operation is the same from time 0 to t3 as from time 0 to t3 of the timing chart in FIG. 9. Moreover, as shown in FIG. 11(g), relay 580 is initially (time 0) closed. In FIG. 11(a), comparator 142 detects that the voltage of the IN1 terminal has transitioned from −V1 to −V2, and in FIG. 11(b), comparator 146 detects that the voltage of the IN2 terminal has transitioned from −V4 to −V3. Relays 162 through 166 are opened and relay 268 is closed, and ramp voltage with voltage −V8 as the starting voltage is applied to gate terminal G of DUT 170. It should be noted that relay 160 remains open. Current flowing to drain terminal D of DUT 170 changes with the changes in the gate voltage. Once the drain current becomes a predetermined current value that specifies the Vth of DUT 170 at time t11, comparator 574 imparts detection signals to switch control unit 553, and switch control unit 553 receives these signals, controls control line 588 and opens relay 580. As a result, there is no further charging of capacitor C 271 and the voltage of the OUT terminal remains the Vth voltage, as shown from time t11 to t4 in FIG. 11(h). Vth high-speed determination is possible by measuring the Vg from time t11 to time t4 using SMU 132.

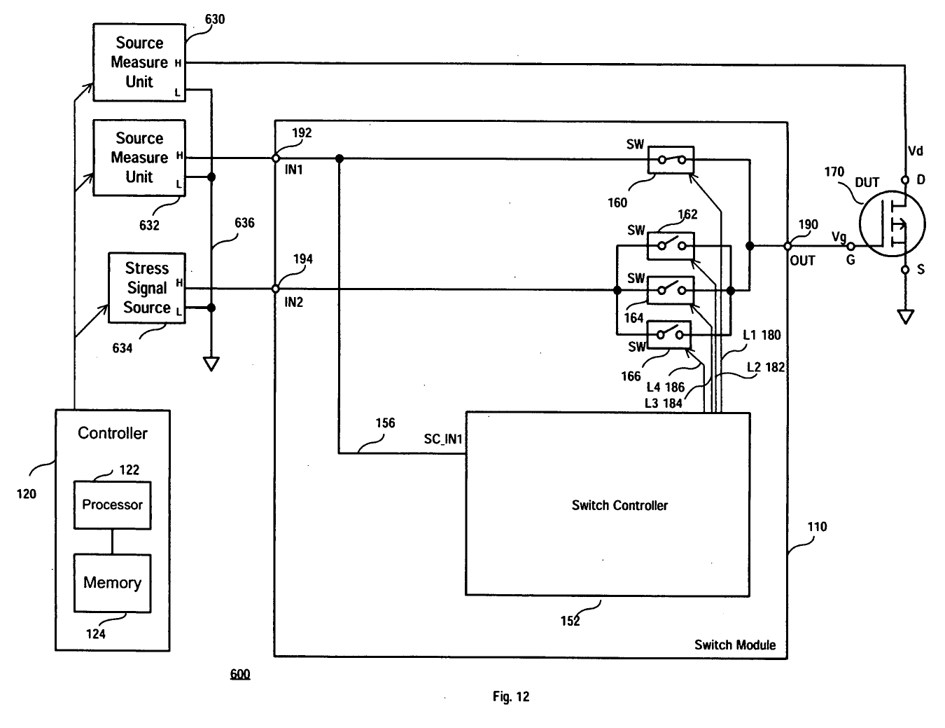

A semiconductor characteristic measurement apparatus 600, wherein the common voltage terminal of the measurement instrument in FIG. 1, that is, the SMU and the stress signal source, is floating, will be described as another working example while referring to FIG. 12. It should be noted that the same reference numbers are used for the components in FIG. 12 that are the same as in FIG. 1.

Each of a SMU 630 connected to drain terminal D of DUT 170, an SSS 634 which applies stress signals to gate terminal G of DUT 170 via switching module 110, and a SMU 632 which applies a predetermined voltage during DC measurement has a common voltage terminal L, respectively, and each of them is connected by a line 636 and connected to a predetermined reference potential. Moreover, source terminal S of DUT 170 is similarly connected to a predetermined reference potential. This reference potential can be ground potential or another potential. The rest of the components and operation are the same as in FIG. 1, and measurement can be accomplished as in FIG. 1 by the connections as described above.

Several working examples of the present disclosure have been described, but a variety of changes and modifications are possible when based on the intent of the present disclosure.

For instance, it is also possible to insert a buffer in front of the noninverted input terminal of the comparator in the above-mentioned working examples.

Moreover, as long as the band and cost are not a problem, it is possible to change the multiple SPST relays, such as relays 160 through 166, to SPMT (single-pole, multiple-throw) switches having the same function in the above-mentioned working examples.

Similarly, as long as the performance of the turn-on resistance is not a problem, it is also possible to change relays 162 through 166 for opening and closing stress signals to a single relay.

In addition, these relays can be changed from semiconductor relays to another type of relay having the same properties.

Moreover, the multiple SMUs can be individual DC measurement instruments, or they can be housed as individual channels inside a DC measurement instrument.

Unless it becomes necessary to modify the setting of SSS 134 during measurement, SSS 134 is not necessarily connected to controller 120 or 220 and can be used in a free-run state, wherein predetermined output signals are output in a series by manual operation.

The controller can be an independent controller or it can be housed inside any of the measurement instruments.

Moreover, it is possible to use one voltage source for reference voltage sources Vref 142 and 144, depending on the signal level of the terminal SC_IN1 and the terminal SC_IN2.

The AC stress signals from the SSS have been described based on an example of AC stress signals superimposed on DC offset signals, but the AC stress signals are not limited to this example.

Modification is also possible whereby the timer inside the switch controller is eliminated and recovery from DC measurement back to stress application is based on signals from the SMU.

Furthermore, by means of semiconductor characteristic measurement apparatus 300, it is possible to connect a dedicated trigger signal source to the terminal IN3 of switch module 310.

Furthermore, the switch module of the present disclosure can be designed as an independent apparatus or it can be designed such that it is housed inside a measurement apparatus.

Furthermore, in each of the timing charts of the present disclosure, the application of a constant voltage to the drain voltage, the measurement at various drain voltage values, and other modifications or combinations thereof such as disclosed in the above-mentioned references fall within the scope of the present disclosure.

Furthermore, the above-mentioned embodiments have been described using as an example the NBTI testing of a PMOSFET, but it is also possible to apply a variety of modifications such that these can be used for PBTI testing of an NMOSFET, and to apply the embodiments of the present disclosure to applications in other fields of DC measurement once AC stress is stopped. Moreover, it is also possible to use the embodiments of the present disclosure for on-the-fly and other BTI testing methods.

It should be understood that the foregoing description is only illustrative of the present embodiments. Various alternatives and modifications can be devised by those skilled in the art without departing from the embodiments disclosed herein. Accordingly, the embodiments are intended to embrace all such alternatives, modifications and variances which fall within the scope of the appended claims.

What is claimed is:

1. A switch module for semiconductor characteristic measurement, comprising
a first input terminal for receiving stress signals from a stress signal source,
a second input terminal for receiving signals from a first non-stress signal source,
a first output terminal for outputting output signals, and
a switch part for controlling the connection of the first output terminal and the first input terminal or the second input terminal,
wherein the switch part detects a first voltage transition of the signals transmitted to the second input terminal and modifies the connection.

2. The switch module according to claim 1, wherein the first non-stress signal source is a source measure unit.

3. The switch module according to claim 1, wherein the stress signal source is either a pulse generator, a source measure unit, or a DC power source.

4. The switch module according to claim 1, wherein the switch part comprises a timer and restores the pre-modification connection for a predetermined time after the first voltage transition has been detected and the connection has been modified.

5. The switch module according to claim 4, wherein the switch part comprises a first relay for opening and closing the connection between the first output terminal and the first input terminal, a second relay for opening and closing the connection between the first output terminal and the second input terminal, and a switch controller for controlling the first and second relays, wherein the switch controller comprises the timer, is connected to the second input terminal, detects the first voltage transition, and controls the first and second relays.

6. The switch module according to claim 5, wherein the first relay is multiple relays connected in parallel.

7. The switch module according to claim 6, wherein the switch controller controls the open and close timing of the multiple first relays such that each of the multiple first relays is opened and closed with slightly shifted timing amongst each other.

8. The switch module according to claim 6, wherein the multiple first relays are controlled such that the number of relays simultaneously closed increases with an increase in the frequency of the signals transmitted to the first input terminal.

9. The switch module according to claim 5, wherein the first relay is a semiconductor relay.

10. The switch module according to claim 1, wherein the switch part detects the first voltage transition, then detects a second voltage transition of signals transmitted to the first input terminal, and modifies the connection.

11. The switch module according to claim 5, wherein the switch controller is also connected to the first input terminal, detects the first voltage transition, then detects the second voltage transition of signals transmitted to the first input terminal, and controls the first and second relays.

12. The switch module according to claim 1, further comprising a third input terminal for receiving signals from the second non-stress signal source and a capacitor connected to the third input terminal,
wherein the switch part controls the connection/disconnection of the first output terminal and the third input terminal instead of controlling the connection/disconnection of the first output terminal and the second input terminal when the first voltage transition is detected and the connection is modified.

13. A switch module for semiconductor characteristic measurement, comprising
a first input terminal for receiving stress signals from a stress signal source,
a second input terminal for receiving signals from a first non-stress signal source,
a fourth input terminal for receiving signals from a third non-stress signal source,
a first output terminal for outputting output signals, and
a switch part for controlling the connection of the first output terminal and the first input terminal or the second input terminal,
wherein the switch part detects a third voltage transition of the signals transmitted to the fourth input terminal and modifies the connection.

14. The switch module according to claim 13, further comprising
a second output terminal,
wherein the second output terminal is connected to a fourth input terminal.

15. A semiconductor characteristic measurement method, comprising
connecting a stress signal source to a first terminal of a DUT via a switch module,
connecting a first non-stress signal source to the switch module,
applying stress signals from the stress signal source to the first terminal,
outputting a first voltage from the first non-stress signal source,
outputting a second voltage from the first non-stress signal source,
connecting the switch module connects the first non-stress signal source to the first terminal which is triggered by the switch module according to the transition from the first voltage to the second voltage, and
measuring the current flowing to the second terminal of the DUT.

16. The measurement method according to claim 15, wherein the stress signal source is either a pulse generator, a source measure unit, or a DC power source.

17. The measurement method according to claim 15, wherein once a predetermined time has passed after the connection of the first non-stress signal source to the first terminal by the switch module, the connection of the first terminal and the first non-stress signal source is disconnected by a timer.

18. The measurement method according to claim 15, wherein once a second predetermined time has passed after the connection of the first non-stress signal source to the first terminal by the switch module, the connection to the first terminal and the first non-stress signal source is disconnected by a timer and the connection of the first terminal and the stress signal source is restored.

19. The measurement method according to claim 15, wherein when the first non-stress signal source is connected to the first terminal by the switch module, the connection of the first non-stress signal source to the first terminal is triggered by a transition of the signals from the stress signal source from the third voltage to the fourth voltage after the voltage transition.

20. The measurement method according to claim 15, wherein the switch module connects the second non-stress signal source and the capacitor to the first terminal instead of connecting the first non-stress signal source to the first terminal and applies ramp waveform.
